(19) United States
(12) Patent Application Publication
(10) Pub. No.: US 2025/0014960 A1
(43) Pub. Date: Jan. 9, 2025

(54) MOLDING COMPOUND LAYERS IN SEMICONDUCTOR PACKAGES

(71) Applicant: Apple Inc., Cupertino, CA (US)

(72) Inventors: Jiongxin LU, San Jose, CA (US); Kunzhong Hu, Cupertino, CA (US); Jun Zhai, Cupertino, CA (US)

(73) Assignee: Apple Inc., Cupertino, CA (US)

(21) Appl. No.: 18/348,934

(22) Filed: Jul. 7, 2023

(51) Int. Cl. H01L 23/31; H01L 21/56; H01L 23/00; H01L 23/498; H01L 25/065

(52) U.S. Cl. CPC H01L 23/315; H01L 21/565; H01L 23/49822; H01L 24/16; H01L 24/32; H01L 24/73; H01L 25/0655; H01L 2224/16225; H01L 2224/32225; H01L 2224/73204; H01L 2924/1815; H01L 2924/182

(57) ABSTRACT

Various embodiments of an integrated circuit (IC) die package are disclosed. An IC die package includes an IC die, an interposer structure electrically connected to the IC die, a first bonding structure, a second bonding structure, and a molding compound layer. The first bonding structure includes a first dielectric layer disposed on the IC die and a first conductive plug disposed in the first dielectric layer. The second bonding structure includes a second dielectric layer disposed on the interposer structure and a second conductive plug disposed in the second dielectric layer. The molding compound layer includes a mold region and a mold cavity.

### FIELD

This disclosure relates to semiconductor packages and, more particularly, to molding compound layers in integrated circuit (IC) die packages.

### BACKGROUND

An IC die package can include two or more IC dies (e.g., system-on-chips (SOCs), logic dies, and/or memory dies) mounted on a package substrate. Power and signal connections between the IC dies can be made through a routing layer. The two or more IC dies can be bonded to the routing layer through hybrid bonding structures and can be encapsulated in a molding compound layer. The molding compound layer can provide mechanical rigidity and environmental protection to the two or more IC dies to prevent moisture and handling damage.

### SUMMARY

Various embodiments of molding compound layers with mold cavities in an IC die package are disclosed. In some embodiments, a structure includes an IC die, an interposer structure electrically connected to the IC die, a first bonding structure, a second bonding structure, and a molding compound layer. The first bonding structure includes a first dielectric layer disposed on the IC die and a first conductive plug disposed in the first dielectric layer. The second bonding structure includes a second dielectric layer disposed on the interposer structure and a second conductive plug disposed in the second dielectric layer. The molding compound layer includes a mold region and a mold cavity.

In some embodiments, an IC die package includes a routing layer, first and second IC dies disposed on the routing layer, first and second bonding structures disposed on the first and second IC dies, respectively, a third bonding structure bonded to the first and second bonding structures and disposed on the routing layer, and an encapsulation layer disposed surrounding the first and second IC dies. The routing layer includes conductive lines and vias. The encapsulation layer includes a mold region and a recessed opening in the mold region.

In some embodiments, a method for fabricating an IC die package with a molding compound layer includes forming a first structure having a first bonding structure on an IC die, forming a second structure having a second bonding structure on an interposer structure, performing a bonding process between the first and second bonding structures to form a bonded structure, placing the bonded structure in a component region between a top and bottom mold-forming structures of a molding system, and performing a molding process in the molding system to form a molding compound layer, having a mold region and a mold cavity, surrounding the bonded structure. The placing of the bonded structure includes aligning a protruding structure of the top mold-forming structure on a portion of the second bonding structure non-overlapping with the first bonding structure.

### BRIEF DESCRIPTION OF THE DRAWINGS

Aspects of this disclosure are best understood from the following detailed description when read with the accompanying figures.

FIG. 1 illustrates a cross-sectional view of a molding compound layer with mold cavities in an IC die package, in accordance with some embodiments.

FIG. 2 illustrates a cross-sectional view of a molding compound layer with mold cavities in another IC die package, in accordance with some embodiments.

FIG. 3 illustrates a cross-sectional view of a molding compound layer with mold cavities in another IC die package, in accordance with some embodiments.

FIG. 4 is a flow diagram of a method for fabricating an IC die package with a molding compound layer having mold cavities, in accordance with some embodiments.

FIG. 5 illustrates a cross-sectional view of an IC die package at a stage of its fabrication process, in accordance with some embodiments.

FIG. 6 illustrates a cross-sectional view of an IC die package at a stage of its fabrication process, in accordance with some embodiments.

FIG. 7 illustrates a cross-sectional view of an IC die package at a stage of its fabrication process, in accordance with some embodiments.

FIG. 8 illustrates a cross-sectional view of an IC die package at a stage of its fabrication process, in accordance with some embodiments.

FIG. 9 illustrates a cross-sectional view of an IC die package at a stage of its fabrication process, in accordance with some embodiments.

FIG. 10 illustrates a cross-sectional view of an IC die package at a stage of its fabrication process, in accordance with some embodiments.

FIG. 11 illustrates a cross-sectional view of an IC die package at a stage of its fabrication process, in accordance with some embodiments.

FIG. 12 illustrates a cross-sectional view of an IC die package at a stage of its fabrication process, in accordance with some embodiments.

FIG. 13 illustrates a cross-sectional view of an IC die package at a stage of its fabrication process, in accordance with some embodiments.

FIG. 14 illustrates a cross-sectional view of an IC die package at a stage of its fabrication process, in accordance with some embodiments.

FIG. 15 illustrates a cross-sectional view of an IC die package at a stage of its fabrication process, in accordance with some embodiments.

FIG. 16 illustrates a cross-sectional view of an IC die package with a molding compound layer having mold cavities at a stage of its fabrication process, in accordance with some embodiments.

FIG. 17 illustrates a cross-sectional view of an IC die package with a molding compound layer having mold cavities at a stage of its fabrication process, in accordance with some embodiments.

FIG. 18 illustrates a cross-sectional view of an IC die package with a molding compound layer having mold cavities at a stage of its fabrication process, in accordance with some embodiments.

FIG. 19 illustrates a cross-sectional view of an IC die package with a molding compound layer having mold cavities at a stage of its fabrication process, in accordance with some embodiments.

FIG. 20 illustrates exemplary systems or devices that can include different IC die packages with molding compound layers having mold cavities, in accordance with some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

An IC die (also referred to as an “IC chip”) can include a compilation of layers with different functionality, such interconnect structures, power distribution networks, logic chips, memory chips, and the like. An IC die package (also referred to as “semiconductor package”) can include multiple IC dies disposed on and electrically connected to routing layers having interposer structures, which can be disposed on and electrically connected to a package substrate. The routing layers and package substrate can provide electrical connections (also referred to as “signal transmission paths” or “metal routings”) between IC dies on the same routing layer and/or between IC dies on different routing layers.

The IC dies can be bonded to the routing layer through top and bottom hybrid bonding structures in a hybrid bonding process. Each of the top hybrid bonding structures can be disposed on and electrically connected to interconnect structures of the IC dies. The bottom hybrid bonding structure can be disposed on and electrically connected to metal lines in the routing layer. Each of the top and bottom hybrid bonding structures can include a dielectric layer and conductive structures disposed in the dielectric layer. The top surfaces (also referred to as “bonding surfaces”) of the top hybrid bonding structures can be brought into contact with the top surface of the bottom hybrid bonding structure during the hybrid bonding process to form fusion bonds between the dielectric layers (e.g., oxide-to-oxide bonds) and metal bonding between the conductive structures (e.g., copper-to-copper bonds).

Each of the IC dies along with the top hybrid bonding structures can be surrounded by a molding compound layer (e.g., a polymeric material layer). The spaces between adjacent IC dies and adjacent hybrid bonding structures can be filled with the molding compound layer. The molding compound layer can be disposed directly on the sidewalls of the IC dies and the top hybrid bonding structures and on the top surface of the bottom hybrid bonding structure. The interface between the molding compound layer and the bottom hybrid bonding structure can be substantially coplanar with the hybrid bonding interfaces between the top and bottom hybrid bonding structures. The molding compound layer can provide mechanical stability and environmental protection to the IC dies and the hybrid bonding structures.

One of the challenges of manufacturing reliable IC die packages is preventing delamination at the hybrid bonding interfaces due to stress induced by the molding compound layer during fabrication and/or reliability testing of the IC die packages. The molding compound layer can have a higher thermal expansion coefficient than that of the materials of the IC dies and/or the hybrid bonding structures. As a result, the molding compound layer can have a greater thermal expansion than that of the IC dies and/or the hybrid bonding structures during high temperature processes performed in the fabrication and/or reliability testing of the IC die packages. Such differences in the thermal expansions can induce peeling stress in the hybrid bonding interfaces at the edges of the IC dies as the molding compound layer is disposed adjacent to the hybrid bonding interfaces without having any space available for thermal expansion. The molding compound layer is constrained on the sides by the IC dies, on the bottom side by the bottom hybrid bonding structure, and on the top side by a carrier.

To address the abovementioned challenges, the present disclosure provides example molding compound layers with mold cavities in IC die packages and example methods of forming the example molding compound layers. In some embodiments, each of the IC dies along with the top hybrid bonding structures in the IC die package can be surrounded by the molding compound layer having one or more mold cavities. In some embodiments, the one or more mold cavities can be disposed between adjacent IC dies and between adjacent top hybrid bonding structures. In some embodiments, the one or more mold cavities can have a U-shaped or any suitable geometric-shaped cross-sectional profile. The one or more mold cavities can reduce the total molding compound volume, thus eliminating or reducing the thermal expansion induced peeling stress at the hybrid bonding interfaces.

In some embodiments, the molding compound layer with the one or more mold cavities can be formed using a molding process (e.g., a transfer molding process or a compression molding process) in a molding system (e.g., a transfer molding system). The molding system can include a bottom mold-forming structure and a top mold-forming structure. The top mold-forming structure can include one or more protruding structures that can create impressions in the molding compound layer to form the one or more mold cavities. Thus the cross-sectional profiles of the one or more mold cavities can be similar to that of the one or more protruding structures. With the use of the one or more protruding structures to form the one or more mold cavities during the molding process, the formation of the one or more mold cavities can be implemented in the fabrication process of the IC die package without increasing the manufacturing time and cost of the IC die package.

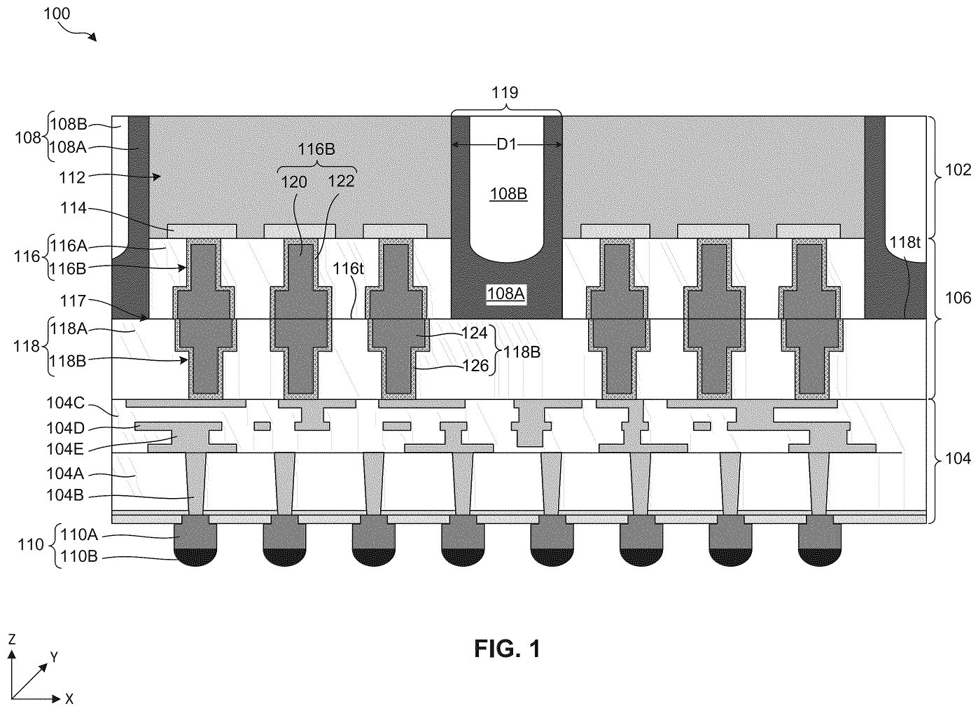

FIG. 1 illustrates a cross-sectional view of an IC die package 100 (also referred to as an “IC chip package 100”), according to some embodiments. In some embodiments, IC die package 100 can include (i) a die layer 102, (ii) a routing layer 104, (iii) a bonding layer 106, (iv) a molding compound layer 108 (also referred to as “encapsulation layer 108”), and (v) conductive bonding structures 110. In some embodiments, die layer 102 can include one or more IC dies 112, each of which can include a high-performance IC die, such as a SoC die, a micro control unit (MCU) die, a microprocessor unit (MPU) die, an accelerated processing unit (APU) die, a central processing unit (CPU) die, a graphics processing unit (GPU) die, and a combination thereof. Though two IC dies 112 are shown in die layer 102, any number of IC dies 112 can be included in die layer 102. In some embodiments, adjacent IC dies 112 can be separated from each other by a distance D1 of about 50 μm to about 70 μm. In some embodiments, IC die 112 can include interconnect structures 114, which can electrically connect devices (not shown) in IC die 112 to underlying routing layer 104 through bonding layer 106. In some embodiments, IC dies 112 can be electrically connected to each other through bonding layer 106 and routing layer 104. In some embodiments, die layer 102 can be electrically connected to overlying die layers or other elements (not shown) of IC die package 100 through a redistribution layer (not shown) or a bonding layer similar to bonding layer 106.

In some embodiments, routing layer 104 can include an interposer structure having (i) a semiconductor substrate 104A, (ii) conductive through-vias 104B disposed in semiconductor substrate 104A, (iii) a dielectric layer 104C disposed on semiconductor substrate 104A, (iv) metal lines 104D disposed in dielectric layer 104C, and (v) metal vias 104E disposed in dielectric layer 104C. In some embodiments, semiconductor substrate 104A can include a silicon substrate. In some embodiments, conductive through-vias 104B can include a metal (such as copper and aluminum), a metal alloy (such as copper alloy and aluminum alloy), or a combination thereof. In some embodiments, dielectric layer 104C can include a stack of dielectric layers. In some embodiments, routing layer 104 can be electrically bonded to an underlying package substrate (not shown) through conductive bonding structures 110. In some embodiments, each of conductive bonding structures 110 can include copper (Cu) bumps 110A and solder bumps 110B. The package substrate can be disposed on and electrically connected to a circuit board (not shown) and can electrically connect IC die package 100 to external devices through the circuit board.

In some embodiments, bonding layer 106 can include one or more first hybrid bonding structures 116 (also referred to as a “top hybrid bonding structures 116”) and a second hybrid bonding structure 118 (also referred to as a “bottom hybrid bonding structure 118”). A bottom surface of each first hybrid bonding structure 116 can be disposed on and electrically connected to interconnect structures 114 of a corresponding IC die 112. A top surface (also referred to as a “bonding surface”) of each first hybrid bonding structure 116 can be disposed on and bonded to a top surface of second hybrid bonding structure 118 through hybrid bonds, as described in detail below. The interfaces between first and second hybrid bonding structures 116 and 118 can be referred to as “hybrid bonding interfaces 117.” The bonding reliability between first and second hybrid bonding structures 116 and 118 can be improved by reducing the risk of delamination between first and second hybrid bonding structures 116 and 118 at hybrid bonding interface 117 with the use of molding compound layer 108, as discussed in detail below.

In some embodiments, each first hybrid bonding structure 116 can include a first dielectric layer 116A and one or more first conductive structures 116B disposed in first dielectric layer 116A. Though three first conductive structures 116B are shown in each first hybrid bonding structure 116, any number of first conductive structures 116B can be included in first hybrid bonding structure 116. In some embodiments, first dielectric layers 116A can include silicon oxide (SiO₂), silicon nitride (SiN), silicon carbide (SiC), silicon oxynitride (SiON), silicon carbon nitride (SiCN), or any other suitable dielectric material. In some embodiments, each first conductive structure 116B can include a first conductive plug 120 and a first liner 122 surrounding first conductive plug 120. In some embodiments, first conductive structures 116B can be liner-free (not shown). Top surfaces of first conductive plugs 120 and first liners 122 can be substantially coplanar with top surface 116t of first dielectric layer 116A. In some embodiments, first conductive plugs 120 can include a conductive material, such as copper (Cu), cobalt (Co), aluminum (Al), any other suitable conductive material, and a combination thereof. In some embodiments, first liners 122 can include a conductive material the same as or different from the material of first conductive plugs 120. In some embodiments, first liners 122 can include titanium (Ti), Cu, or other suitable conductive material.

In some embodiments, second hybrid bonding structure 118 can include a second dielectric layer 118A and one or more second conductive structures 118B disposed in second dielectric layer 118A. Though six second conductive structures 118B are shown in second hybrid bonding structure 118, any number of second conductive structures 118B can be included in second hybrid bonding structure 118. In some embodiments, second dielectric layer 118A can include a dielectric material the same as or different from first dielectric layer 116A. In some embodiments, each second conductive structures 118B can include a second conductive plug 124 and a second liner 126 surrounding second conductive plug 124. In some embodiments, second conductive structures 118B can be liner-free (not shown). Top surfaces of second conductive plugs 124 and second liners 126 can be substantially coplanar with top surface 118t of second dielectric layer 118A. In some embodiments, second conductive plugs 124 and second liners 126 can include a conductive material the same as or different from first conductive plugs 120 and first liners 122, respectively.

First and second dielectric layers 116A and 118A can be bonded to each other through dielectric-to-dielectric fusion bonds, and first and second conductive structures 116B and 118B can be bonded to each other through metal-to-metal bonds. The dielectric-to-dielectric fusion bonds and metal-to-metal bonds can be at hybrid bonding interface 117. In some embodiments, the number of second conductive structures 118B can be equal to the total number of first conductive structures 116B. Each second conductive structure 118B can be bonded to a corresponding one of first conductive structures 116B.

In some embodiments, molding compound layer 108 can surround each IC die 112 and each first hybrid bonding structure 116 and can be disposed on second hybrid bonding structure 118. In some embodiments, molding compound layer 108 can include one or more mold regions 108A and a mold cavity 108B (also referred to as a “recessed opening 108B”) disposed in each mold region 108A. In some embodiments, except for mold regions 108A at the periphery of IC die package 100, mold regions 108A can be disposed in inter-die regions 119, each of which is between adjacent IC dies and between adjacent first hybrid bonding structures 116. Though one inter-die region 119 with mold region 108A is shown in FIG. 1, IC die package 100 can include any number of similar inter-die regions 119 with mold regions 108A between other adjacent IC dies and other adjacent first hybrid bonding structures 116. In some embodiments, mold regions 108A can be disposed directly on sidewalls of IC dies 112 and first dielectric layers 116A of first hybrid bonding structures 116. Mold regions 108A can also be disposed directly on top surface 118t of second dielectric layer 118A of second hybrid bonding structure 118. In some embodiments, the interfaces between mold regions 108A and top surface 118t of second dielectric layer 118A can be substantially coplanar with hybrid bonding interface 117. In some embodiments, mold regions 108A can include a molding compound, an epoxy, a resin, or any other suitable encapsulation material. In some embodiments, mold region 108A in inter-die region 119 can have a volume of about 10% to about 50% of a volume of inter-die region 119 to provide adequate mechanical stability and environmental protection to IC dies 112 and first hybrid bonding structures 116.

In some embodiments, except for mold cavities 108B at the periphery of IC die package 100, mold cavities 108B can be disposed in inter-die regions 119. Though one inter-die region 119 with mold cavity 108B is shown in FIG. 1, IC die package 100 can include any number of similar inter-die regions 119 with mold cavities 108B between other adjacent IC dies and other adjacent first hybrid bonding structures 116. In some embodiments, mold cavities 108B can be disposed on second dielectric layer 118A of second hybrid bonding structure 118 and can be separated from top surface 118t of second dielectric layer 118A by portions of mold regions 108A. In some embodiments, mold cavities 108B can extend below the interfaces between IC dies and first hybrid bonding structures 1116. In some embodiments, mold cavities 108B can have a U-shaped or any suitable geometric-shaped (e.g., rectangular, triangular, etc.) cross-sectional profile. In some embodiments, mold cavity 108B in inter-die region 119 can have a volume of about 50% to about 90% of the volume of inter-die region 119. Within this volume range, mold cavity 108B can reduce overall thermal expansion of mold regions 108A without inducing peeling stress at hybrid bonding interfaces 117 during high temperature processes performed in the fabrication and/or reliability testing of IC die package 100. Though all mold cavities 108B are shown to be disposed in all mold regions 108A in FIG. 1, one or more mold regions 108A can be mold cavity-free (not shown). In some embodiments, mold regions 108A at the periphery of IC die package 100 can be mold cavity-free (not shown).

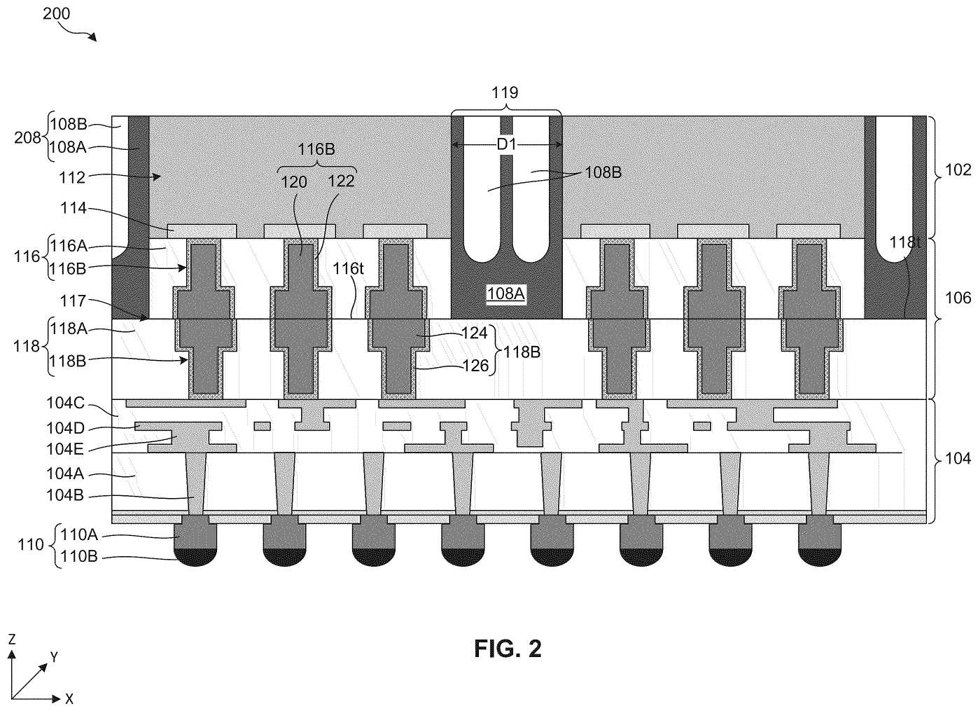

FIG. 2 illustrates a cross-sectional view of an IC die package 200, according to some embodiments. The discussion of IC die package 100 applies to IC die package 200, unless mentioned otherwise. The discussion of elements in FIGS. 1 and 2 with the same annotations applies to each other, unless mentioned otherwise. In some embodiments, IC die package 200 can include molding compound layer 208. The discussion of molding compound layer 108 applies to molding compound layer 208, unless mentioned otherwise. In some embodiments, molding compound layer 208 can include one or more mold regions 108A and a plurality of mold cavities 108B disposed in each mold region 108A, as shown in FIG. 2, instead of a single mold cavity 108B in each mold region 108A, as shown FIG. 1. In some embodiments, the total volume of the plurality of mold cavities 108B in inter-die region 119 can be about 50% to about 90% of the volume of inter-die region 119 to reduce overall stress of mold regions 108A during high temperature processes performed in the fabrication and/or reliability testing of IC die package 200. Though two mold cavities 108B are shown in inter-die region 119 of FIG. 2, any number of mold cavities 108B can be in each inter-die region 119.

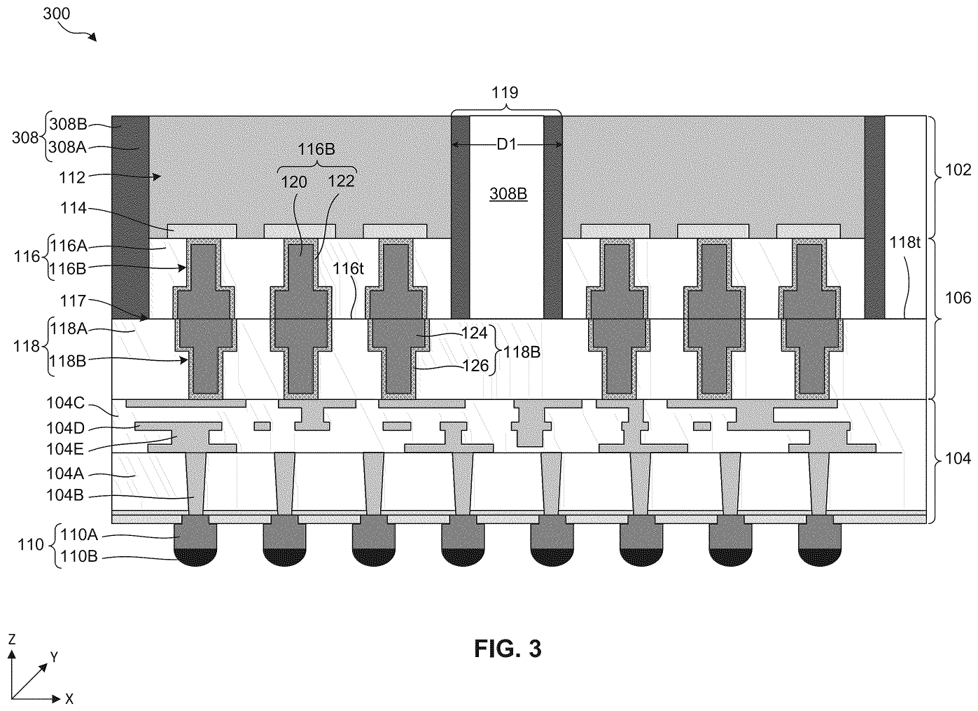

FIG. 3 illustrates a cross-sectional view of an IC die package 300, according to some embodiments. The discussion of IC die package 100 applies to IC die package 300, unless mentioned otherwise. The discussion of elements in FIGS. 1 and 3 with the same annotations applies to each other, unless mentioned otherwise. In some embodiments, IC die package 300 can include molding compound layer 308. The discussion of molding compound layer 108 applies to molding compound layer 308, unless mentioned otherwise. In some embodiments, molding compound layer 308 can include one or more mold regions 308A and a mold cavity 308B disposed in each mold region 308A. In some embodiments, mold cavities 308B can extend to top surface 118t of second dielectric layer, unlike mold cavities 108B of FIG. 1. In some embodiments, mold cavities 308B can have a rectangular-shaped or any suitable geometric-shaped cross-sectional profile. Though a single mold cavity 308B is shown in inter-die region 119 of FIG. 3, any number of mold cavities 308B can be in each inter-die region 119. In some embodiments, mold cavities 108B can have a U-shaped or any suitable geometric-shaped (e.g., rectangular, triangular, etc.) cross-sectional profile. In some embodiments, mold cavity 308B in each inter-die region 119 can have a volume of about 50% to about 90% of the volume of inter-die region 119 to reduce stress induced by mold regions 308A during high temperature processes performed in the fabrication and/or reliability testing of IC die package 300.

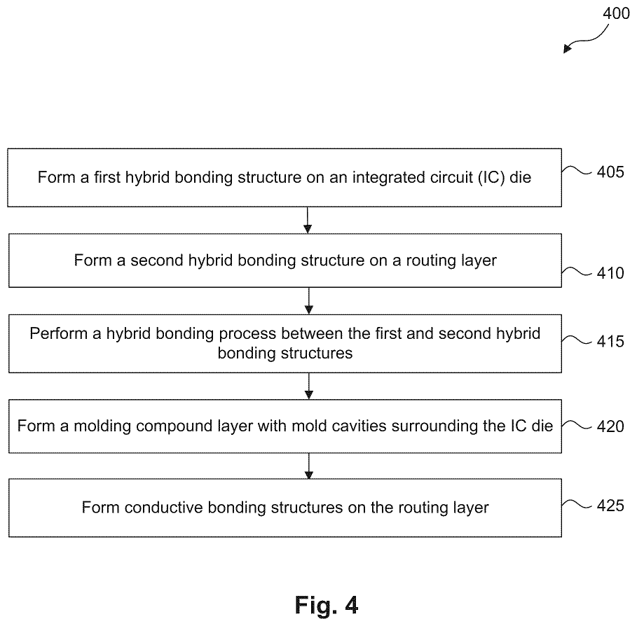

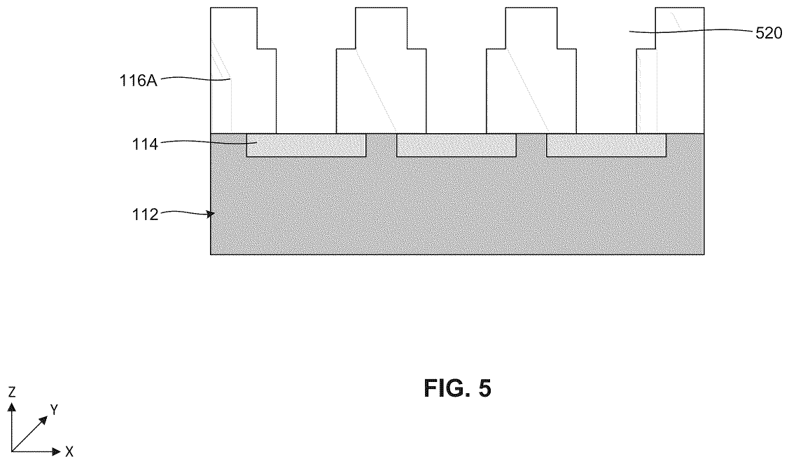

FIG. 4 is a flow diagram of an example method 400 for fabricating IC die package 100 shown in FIG. 1, according to some embodiments. For illustrative purposes, the operations illustrated in FIG. 4 will be described with reference to the example fabrication process for fabricating IC die package 100 as illustrated in FIGS. 5-19. FIGS. 5-19 are cross-sectional views of IC die package 100 at various stages of fabrication, according to some embodiments. Operations can be performed in a different order or not performed depending on specific applications. It should be noted that method 400 may not produce a complete IC die package 100. Accordingly, it is understood that additional processes can be provided before, during, and after method 400, and that some other processes may only be briefly described herein. The discussion of elements in FIGS. 1 and 5-19 with the same annotations applies to each other, unless mentioned otherwise.

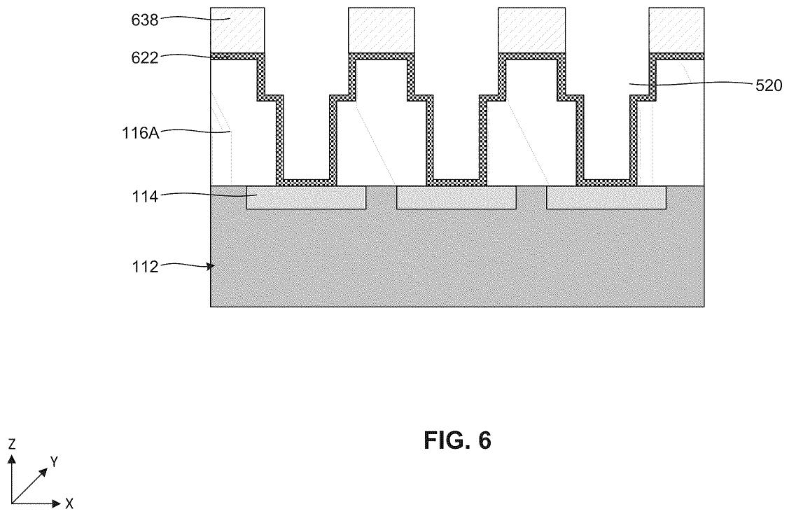

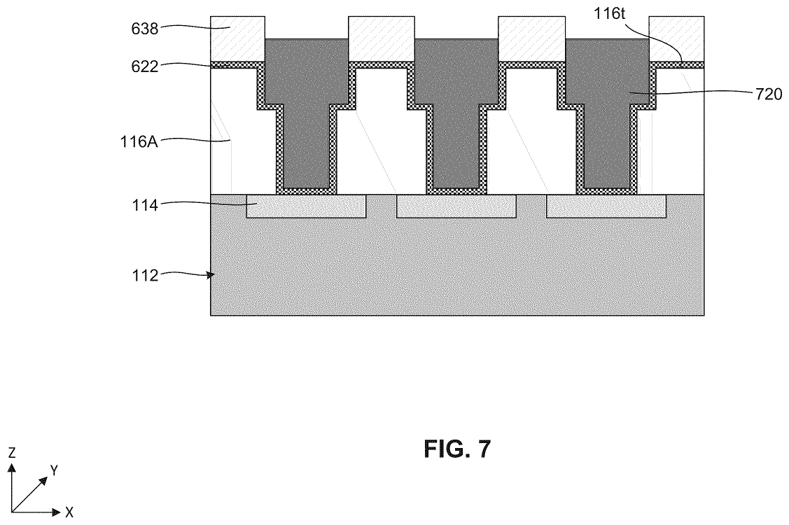

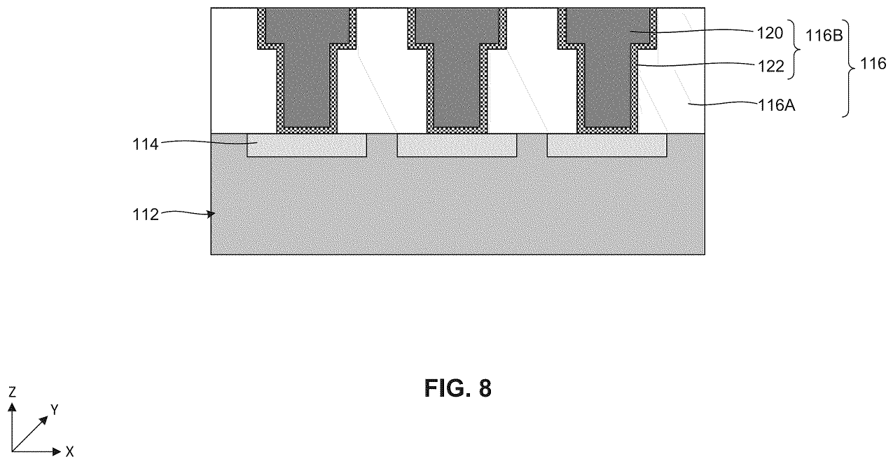

Referring to FIG. 4, in operation 405, a first hybrid bonding structure is formed on an IC die. For example, as described with reference to FIGS. 5-8, first hybrid bonding structure 116 is formed on IC die 112. In some embodiments, the formation of first hybrid bonding structure 116 can include sequential operations of (i) depositing first dielectric layer 116A on IC die 112, as shown in FIG. 5, (ii) etching first dielectric layer 116A to form openings 520 on interconnect structures 114, as shown in FIG. 5, (iii) depositing a conductive layer 622 having the material of first liner 122 on top surfaces 116t of first dielectric layer 116A and along sidewalls of openings 520, as shown in FIG. 6, (iv) forming a patterned photoresist layer 638 on conductive layer 622, as shown in FIG. 6, (v) depositing, using an electroplating process or other suitable conductive material deposition process, a conductive layer 720 having the material of first conductive plug 120 to fill openings 520 and extend a distance over top surfaces 116t of first dielectric layer 116A, as shown in FIG. 7, (vi) removing patterned photoresist layer 638, as shown in FIG. 8, and (vii) performing a chemical mechanical polishing (CMP) process to coplanarize top surfaces of first conductive plugs 120 and first liners 122 with top surfaces 116t of first dielectric layer 116A, as shown in FIG. 8. In some embodiments, operation (iii) can be omitted to form first hybrid bonding structure 116 without first liner 122.

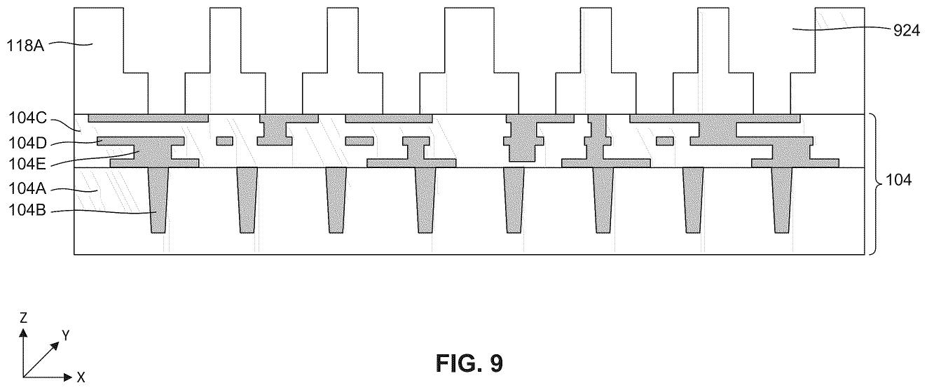

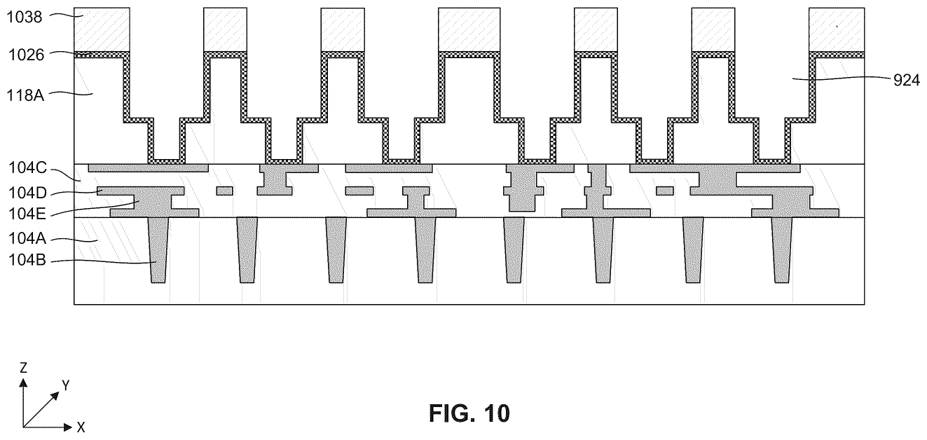

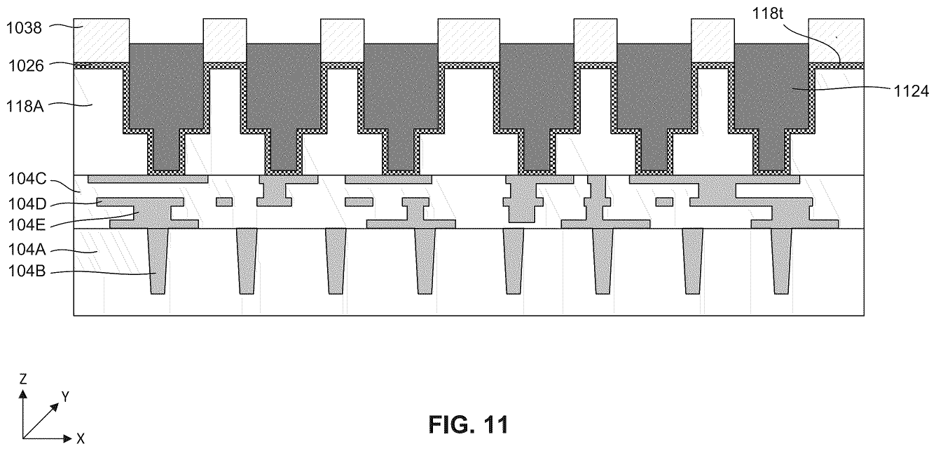

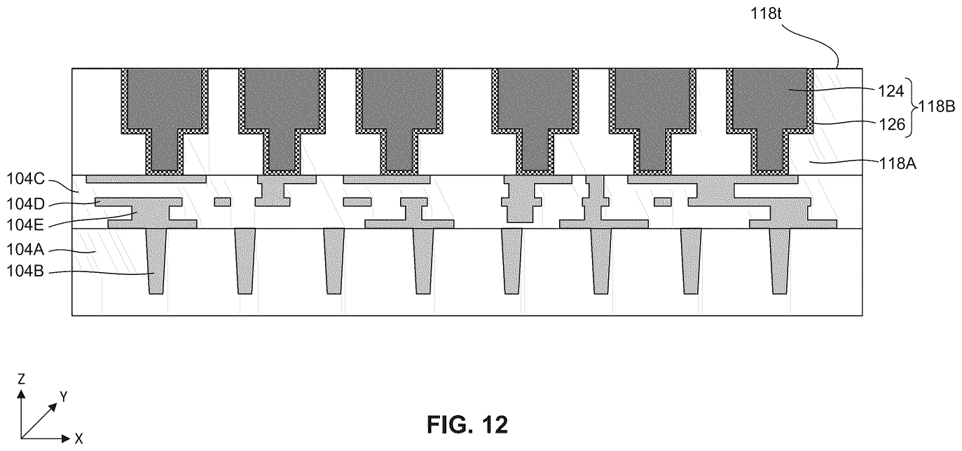

Referring to FIG. 4, in operation 410, a second hybrid bonding structure is formed on a routing layer. For example, as described with reference to FIGS. 9-12, second hybrid bonding structure 118 is formed on routing layer 104. In some embodiments, the formation of second hybrid bonding structure 118 can include sequential operations of (i) depositing second dielectric layer 118A on routing layer 104, as shown in FIG. 9, (ii) etching second dielectric layer 124 to form openings 924 on metal lines 104D, as shown in FIG. 9, (iii) depositing a conductive layer 1026 having the material of second liner 126 on top surfaces 118t of second dielectric layer 124 and along sidewalls of openings 1026, as shown in FIG. 10, (iv) forming a patterned photoresist layer 1038 on conductive layer 1026, as shown in FIG. 10, (v) depositing, using an electroplating process or other suitable conductive material deposition process, a conductive layer 1124 having the material of second conductive plug 124 to fill openings 924 and extend a distance over top surfaces 118t of second dielectric layer 118A, as shown in FIG. 11, (vi) removing patterned photoresist layer 1038, as shown in FIG. 12, and (vii) performing a CMP process to coplanarize top surfaces of second conductive plugs 124 and second liners 126 with top surfaces 118t of second dielectric layer 118A, as shown in FIG. 12. In some embodiments, operation (iii) can be omitted to form second hybrid bonding structure 118 without second liners 126. In some embodiments, operation 410 can be formed prior to operation 405 and operation 415 can follow operation 405.

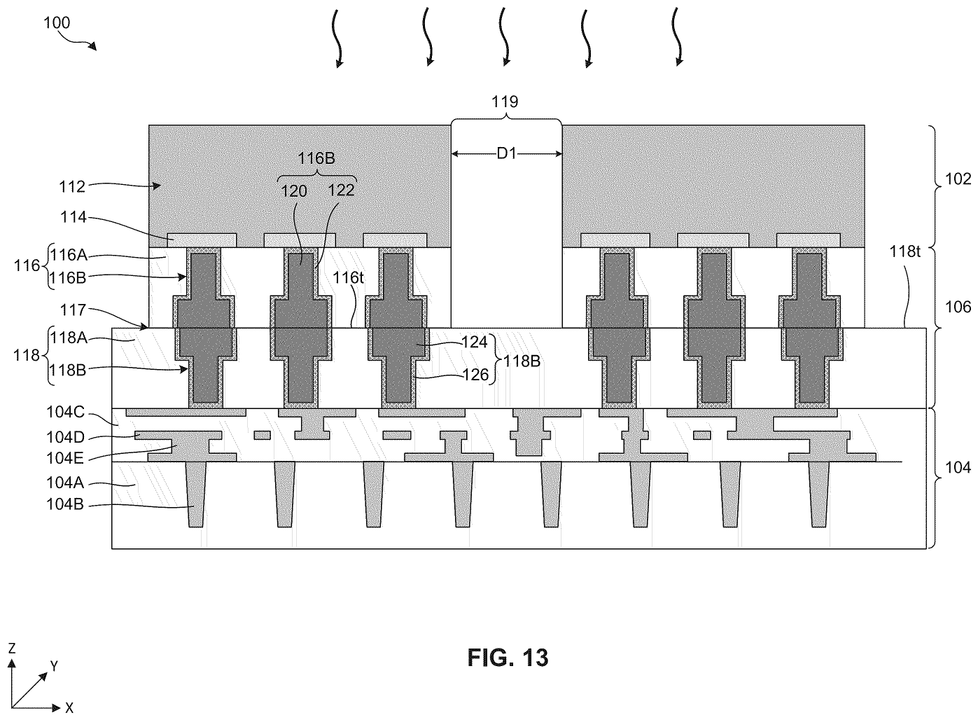

Referring to FIG. 4, in operation 415, a hybrid bonding process is performed between the first and second hybrid bonding structures. For example, as described with reference to FIG. 13, a hybrid bonding process is performed between first and second hybrid bonding structures 116 and 118. In some embodiments, performing the hybrid bonding process can include sequential operations of (i) performing an activation process with a plasma (e.g., hydrogen plasma) on top surfaces of first dielectric layer 116A, first conductive structures 116B, second dielectric layer 118A, and second conductive structures 118B, (ii) aligning first conductive structures with corresponding second conductive structures 118B and bringing top surfaces 116t of first dielectric layer 116A in contact with top surfaces 118t of second dielectric layer 118A, as shown in FIG. 13, and (iii) performing an anneal process on the structure of FIG. 13 at a temperature lower than the melting temperature of the material of first and second conductive plugs 120 and 124 to form the structure of FIG. 13. In some embodiments, first and second conductive structures 116B and 118B may be not be in contact with each other after the aligning in operation (ii) and there may be air gaps present between first and second conductive structures 116B and 118B. First and second conductive structures 116B and 118B can expand and make contact with each other during the anneal process to form the metal-to-metal fusion bonds.

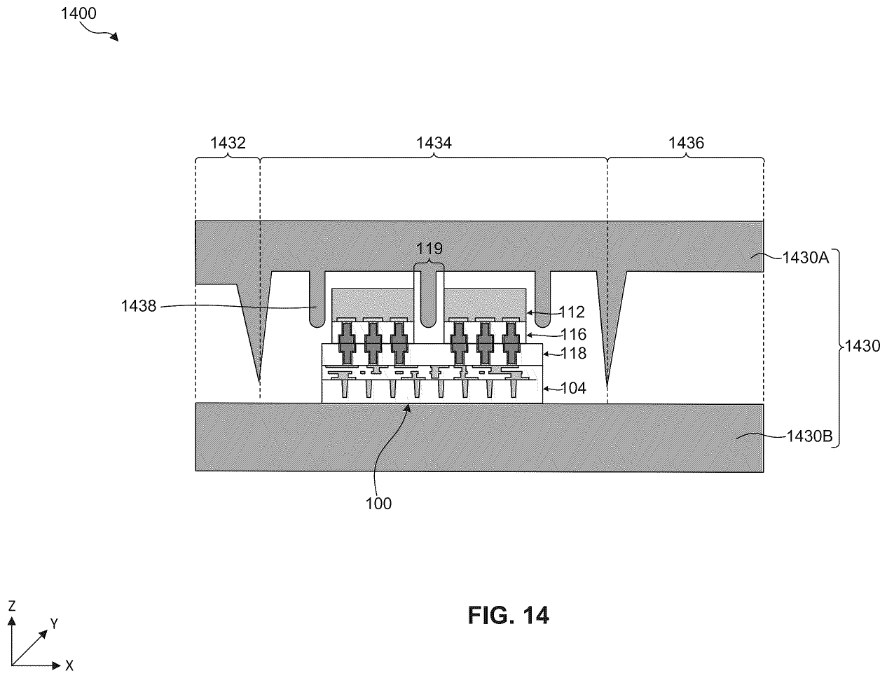

Referring to FIG. 4, in operation 420, a molding compound layer with mold cavities is formed surrounding the IC die. For example, as described with reference to FIGS. 14-17, molding compound layer 108 with mold regions 108A and mold cavities 108B is formed surrounding IC dies 112. In some embodiments, molding compound layer 108 can be formed using a molding process in a molding system 1400, as shown in FIG. 14.

In some embodiments, molding system 1400 can include a mold-forming structure 1430, which can include a top mold-forming structure 1430A (also referred to as a “top chase 1430A”) and a bottom mold-forming structure 1430B (also referred to as a “bottom chase 1430B”). In some embodiments, molding system 1400 can further include a gate region 1432, a component region 1434, and a vent region 1434 disposed between top and bottom mold-forming structures 1430A and 1430B. In some embodiments, the portion of top mold-forming structure 1430A in component region 1434 can include protruding structures 1438, which can create impressions in molding compound layer 108 to form mold cavities 108B, as discussed in detail below. Thus the cross-sectional profiles and structure dimensions of mold cavities 108B can be similar to those of protruding structures 1438.

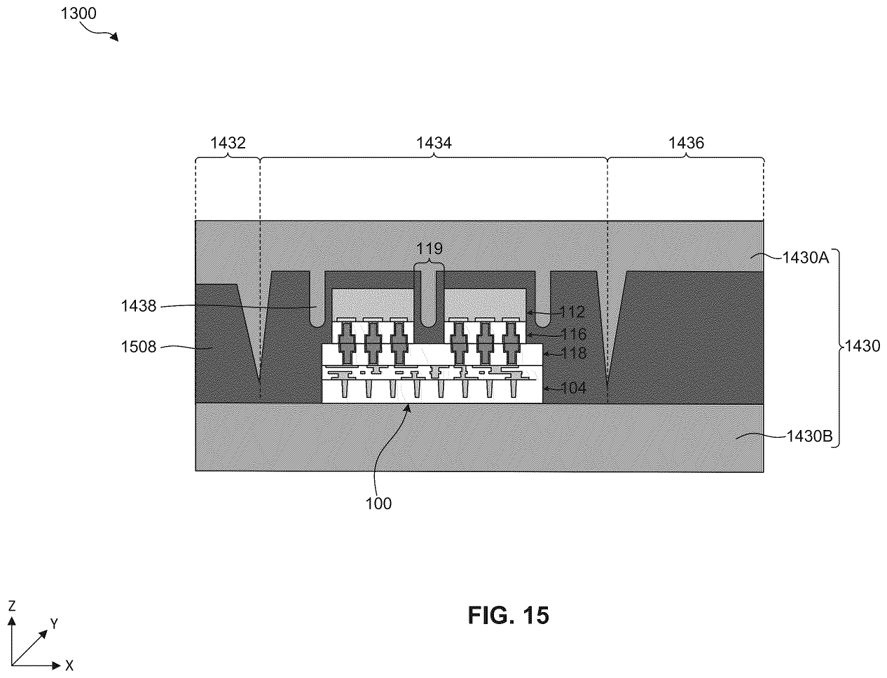

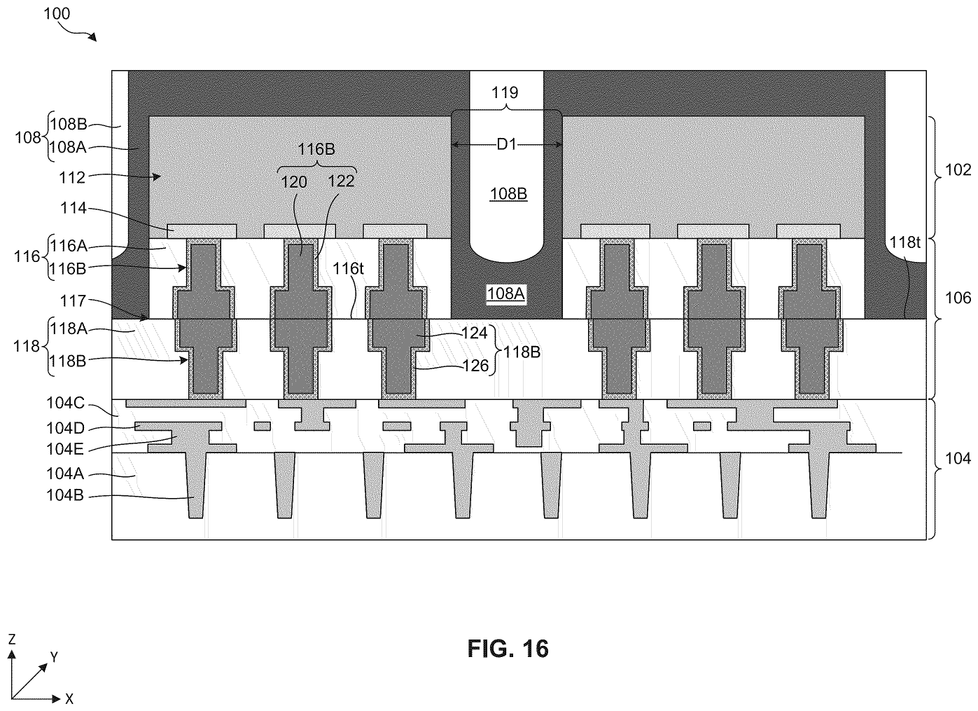

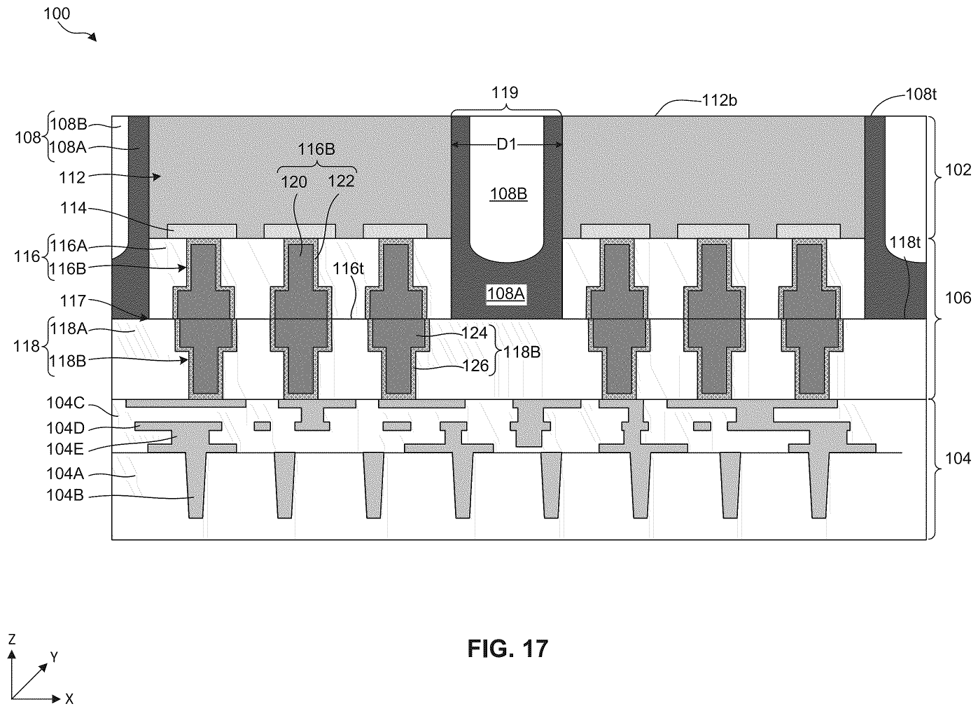

The formation of molding compound layer 108 can include sequential operations of (i) placing the intermediate structure of IC die package 100 in FIG. 13 in component region 1434 such that protruding structures 1438 can be aligned to and extends into inter-die regions 119, as shown in FIG. 14, (ii) introducing fluidic molding compound (not shown) into component region 1434 through gate region 1432 until vent region 1436 is filled, (iii) performing a curing process on the fluidic molding compound to form molding compound layer 1508, as shown in FIG. 15, (iv) removing top mold-forming structure 1430A to expose molding compound layer 1508, (v) removing portions of molding compound layer 1508 that are formed in gate region 1432 and vent region 1436 to form molding compound layer 108 of FIG. 16, and (vi) performing a CMP process on molding compound layer 108 of FIG. 16 to coplanarize top surfaces 108t of mold regions 108A of molding compound layer 108 with back surfaces 112b of IC dies 112, as shown in FIG. 17. In some embodiments, the intermediate structure of IC die package 100 in FIG. 13 can be bonded to a carrier substrate (not shown) prior to placing it in molding system 1400 for the molding process. Molding system 1400 can include other components, such as clamping structures, reservoirs, and fluid chamber, which are not shown for simplicity.

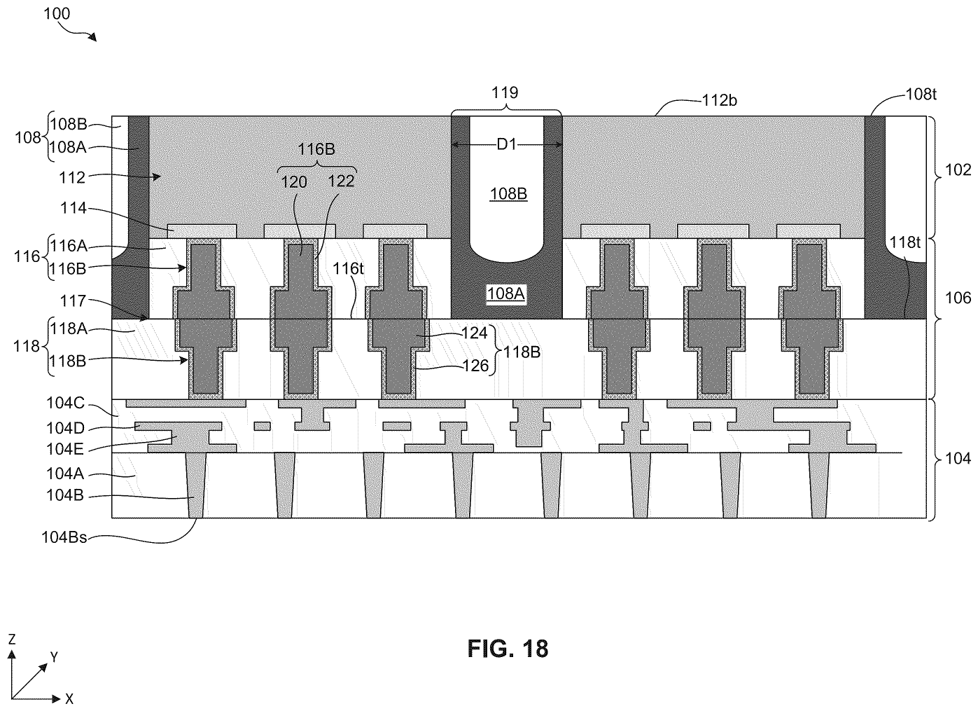

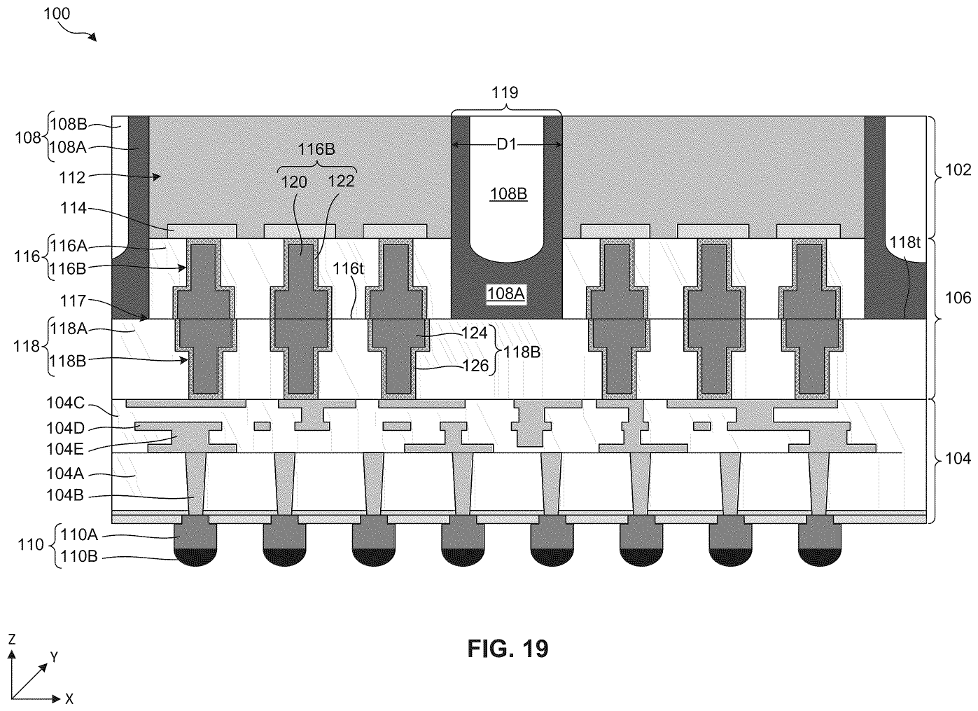

Referring to FIG. 4, in operation 425, conductive bonding structures are formed on the routing layer. For example, as described with reference to FIGS. 18 and 19, conductive bonding structures 110 are formed on routing layer 104. In some embodiments, the formation of conductive structures can include sequential operations of (i) performing a CMP process or an etching process on semiconductor substrate 104A to expose bottom surfaces 104Bs of conductive through-vias 104B, as shown in FIG. 18, and (ii) forming conductive bonding structures 110 on bottom surfaces 104Bs, as shown in FIG. 19.

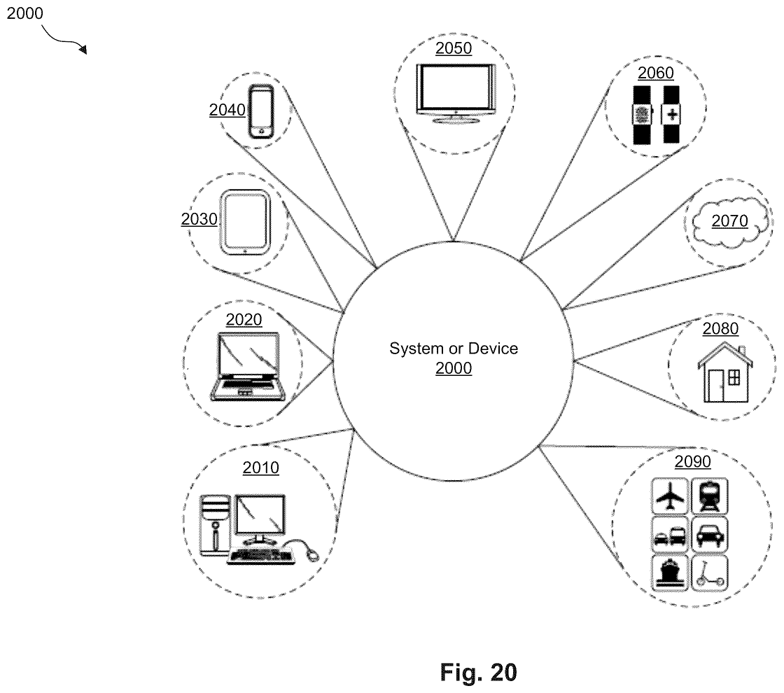

FIG. 20 is an illustration of exemplary systems or devices that can include the disclosed embodiments. System or device 2000 can incorporate one or more of the disclosed embodiments in a wide range of areas. For example, system or device 2000 can be implemented in one or more of a desktop computer 2010, a laptop computer 2020, a tablet computer 2030, a cellular or mobile phone 2040, and a television 2050 (or a set-top box in communication with a television).

Also, system or device 2000 can be implemented in a wearable device 2060, such as a smartwatch or a health-monitoring device. In some embodiments, the smartwatch can have different functions, such as access to email, cellular service, and calendar functions. Wearable device 2060 can also perform health-monitoring functions, such as monitoring a user's vital signs and performing epidemiological functions (e.g., contact tracing and providing communication to an emergency medical service). Wearable device 2060 can be worn on a user's neck, implantable in user's body, glasses or a helmet designed to provide computer-generated reality experiences (e.g., augmented and/or virtual reality), any other suitable wearable device, and combinations thereof.

Further, system or device 2000 can be implemented in a server computer system, such as a dedicated server or on shared hardware that implements a cloud-based service 2070. System or device 2000 can be implemented in other electronic devices, such as a home electronic device 2080 that includes a refrigerator, a thermostat, a security camera, and other suitable home electronic devices. The interconnection of such devices can be referred to as the “Internet of Things” (IoT). System or device 2000 can also be implemented in various modes of transportation 2090, such as part of a vehicle's control system, guidance system, and/or entertainment system. The systems and devices illustrated in FIG. 20 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
an integrated circuit (IC) die;
an interposer structure electrically connected to the IC die;
a first bonding structure, comprising:
a first dielectric layer disposed on the IC die; and
a first conductive plug disposed in the first dielectric layer;
a second bonding structure bonded to the first bonding structure, wherein the second bonding structure comprises:
a second dielectric layer disposed on the interposer structure; and
a second conductive plug disposed in the second dielectric layer; and
a molding compound layer disposed on the second bonding structure, wherein the molding compound layer comprises a mold region and a mold cavity.

2. The structure of claim 1, wherein the molding compound layer surrounds the IC die and the first bonding structure.

3. The structure of claim 1, wherein the mold region is disposed directly on sidewalls of the IC die and the first dielectric layer.

4. The structure of claim 1, wherein the mold region and the mold cavity are disposed on a portion of the second bonding structure non-overlapping with the first bonding structure.

5. The structure of claim 1, wherein the mold cavity extends below an interface between the IC die and the first bonding structure.

6. The structure of claim 1, wherein the mold cavity extends to a surface portion of the second bonding structure non-overlapping with the first bonding structure.

7. The structure of claim 1, wherein the mold cavity comprises a U-shaped cross-sectional profile.

8. The structure of claim 1, wherein the mold cavity comprises first and second mold cavities disposed in the mold region.

9. The structure of claim 1, wherein an interface between the mold region and the second bonding structure is substantially coplanar with an interface between the first and second bonding structures.

10. The structure of claim 1, wherein a top surface of the mold region is substantially coplanar with a back surface of the IC die.

11. An integrated circuit (IC) die package, comprising:
a routing layer comprising conductive lines and vias;
first and second IC dies disposed on the routing layer;
first and second bonding structures disposed on the first and second IC dies, respectively;
a third bonding structure bonded to the first and second bonding structures and disposed on the routing layer; and
an encapsulation layer disposed surrounding the first and second IC dies, wherein the encapsulation layer comprises a mold region and a recessed opening in the mold region.

12. The IC die package of claim 11, wherein the recessed opening is disposed between the first and second IC dies.

13. The IC die package of claim 11, wherein the recessed opening is disposed between the first and second bonding structures.

14. The IC die package of claim 11, wherein the recessed opening is disposed on a portion of the third bonding structure non-overlapping with the first and second bonding structures.

15. The IC die package of claim 11, wherein a surface portion of the third bonding structure non-overlapping with the first and second bonding structures is exposed in the recessed opening.

16. The IC die package of claim 11, wherein the recessed opening extends below an interface between the first IC die and the first bonding structure.

17. A method, comprising:
forming a first structure comprising a first bonding structure on an integrated circuit (IC) die;
forming a second structure comprising a second bonding structure on an interposer structure;
performing a bonding process between the first and second bonding structures to form a bonded structure;
placing the bonded structure in a component region between a top and bottom mold-forming structures of a molding system, wherein placing the bonded structure comprises aligning a protruding structure of the top mold-forming structure on a portion of the second bonding structure non-overlapping with the first bonding structure; and
performing a molding process in the molding system to form a molding compound layer, comprising a mold region and a mold cavity, surrounding the bonded structure.

18. The method of claim 17, wherein performing the molding process comprises forming the mold cavity with a cross-sectional profile of the protruding structure.

19. The method of claim 17, wherein performing the molding process comprises:
introducing a fluidic molding compound into the component region; and
curing the fluidic molding compound to form the molding compound layer.

20. The method of claim 17, wherein performing the molding process comprises performing a polishing process on the molding compound layer to coplanarize a top surface of the mold region with a back surface of the IC die.
